(19) United States
(12) Patent Application Publication
(10) Pub. No.: US 2019/0283365 A1
(43) Pub. Date: Sep. 19, 2019

(54) MULTI-LAYER CLAD THERMAL SPREADING COMPOSITE

(71) Applicant: EMS ENGINEERED MATERIALS SOLUTIONS, LLC, Attleboro, MD (US)

(72) Inventor: Joseph Mennucci, Manville, RI (US)

(21) Appl. No.: 16/356,565

(22) Filed: Mar. 18, 2019

Related U.S. Application Data
(60) Provisional application No. 62/644,178, filed on Mar. 16, 2018.

(51) Int. Cl. B32B 15/01; B32B 3/14; B32B 15/02; F28F 21/08

(52) U.S. Cl. CPC B32B 15/015; B32B 3/14; B32B 15/02; H05K 7/2039; F28F 21/083; B32B 2250/03; B32B 2307/304; F28F 21/085

(57) ABSTRACT

A multiple layer metallic laminate including a metallic layer of high heat dispersion characteristics and a thermal barrier material interlaid within the metallic layer. The laminate can include multiple metallic layers having either high heat dispersion characteristics or lesser heat dispersion characteristics. The thermal barrier material can separate portions of the high heat dispersion metallic layers from one another to minimize heat dispersion into isolated portions.

### FIELD OF THE INVENTION

The present invention relates to a laminate composite having multiple layers of a particular metal or metal alloy configured to have heat spreading capabilities.

### BACKGROUND OF THE INVENTION

Portable electronic devices (PEDs) utilize processors that generate a tremendous amount of heat. In order to dissipate the heat, PEDs can utilize a variety of materials that serve the dual purpose of spreading the heat as well as protecting the contents within the PEDs. Many PEDS today typically utilize stainless steel mono-metal for mechanical integrity and thermal heat dissipation. However, while the stainless steel provides good mechanical functionality, it has limited thermal performance. On the flip side, a copper mono-metal would have good thermal dispersion performance, but poor mechanical functionality. In addition, there is a need to control the direction of the heat dispersion within the material.

Therefore, there is a need for a material that has a combination of good mechanical functionality and thermal performance, as well as the ability to control the direction of the thermal dispersion.

### SUMMARY OF THE INVENTION

A multiple layer laminate composite or system is described herein having improved thermal dispersion properties over known embodiments. The metallic laminate composite can include a first metallic layer having high heat dispersion characteristics and a thermal barrier material interlaid within the first metallic layer, the thermal barrier material preventing heat dispersion. In an aspect, the thermal barrier material is interlaid into the first metallic layer through bonding. In some instances, the barrier blocking material is harder than the first metallic layer. The thermal barrier material is interlard within the first metallic layer to prevent heat dispersion throughout a portion of the first metallic layer. In an aspect, the first metallic layer of the metallic laminate composite has a length and a width, and the thermal barrier material includes at least one linear component interlaid within and along the length of the first metallic layer. In some embodiments, there are two linear components that are interlaid within the first metallic layer to provide three distinct portions of the first metallic layer. The linear components can include wire.

In an aspect, the first metallic layer of the metallic laminate composite includes copper, copper alloy, aluminum, aluminum alloy, and the like. The thermal barrier material of the metallic laminate composite can include stainless steel and similar metals. In an aspect, the metallic laminate composite can include, along with the barrier material and first metallic layer, a second metallic layer bonded to the first metallic layer, the second layer having lesser heat dispersion characteristics. In some aspects, the second layer can come in contact with the thermal barrier material. In addition, the second metallic layer can be the same material as the thermal barrier material. In some aspects, the second metallic layer can include stainless steel addition, the metallic laminate composite can have three metallic layers, with two of the metallic layers having lesser heat dispersion characteristics and oriented on opposite sides of the first metallic layer, having the thermal barrier material interlaid within, the first metallic layer having high thermal dispersion characteristics. In other aspects, the metallic laminate composite can include three metallic layers, two metallic layers having high thermal dispersion properties and one having low thermal dispersion properties, with the high thermal dispersion layers sandwiching the low thermal dispersion layer, with both the outer high thermal dispersion property layers having thermal barrier material interlaid within.

These and other aspects of the invention can be realized from a reading and understanding of the detailed description and drawings.

### BRIEF :DESCRIPTION OF THE DRAWINGS

FIG. 1 is a schematic representation of a multiple layer metallic laminate composite according to the invention.

FIG. 2 illustrates a thermal blocking material interlaid with a metal having high thermal dispersion properties according to an aspect of the present invention.

FIG. 3 is a schematic representation of a multiple layer metallic laminate composite with a thermal blocking material interlaid within showing high thermal spread in a directional matter according to an aspect.

FIG. 4 is a schematic representation of materials used to make the multiple layer metallic laminate composite of FIG. 1 before bonding.

FIGS. 5-6 are schematic representations of a multiple layer metallic laminate composite before and after bonding according to an aspect of the present invention.

FIGS. 7-9 are schematic representations of various multiple layer metallic laminate composites before bonding according to an aspect of the present invention.

FIG. 10 illustrates heat spread comparison between stainless steel and a multiple layer metallic laminate composite.

FIG. 11 is a cross sectional view of a multiple layer metallic laminate composite made according to aspects of the present invention.

FIG. 12 is a graphical representation of thermal spreading resistance across various metals and multiple layer metallic laminate composites.

FIG. 13 is a graphical representation of cladding relationships according to an aspect of the present invention.

### DETAILED DESCRIPTION OF THE INVENTION

In the following detailed description of the embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention. Electrical, mechanical, and structural changes may be made to the embodiments without departing from the spirit and scope of the present teachings. The following detailed description is therefore not to be taken in a limiting sense, and the scope of the present disclosure is defined by the appended claims and their equivalents.

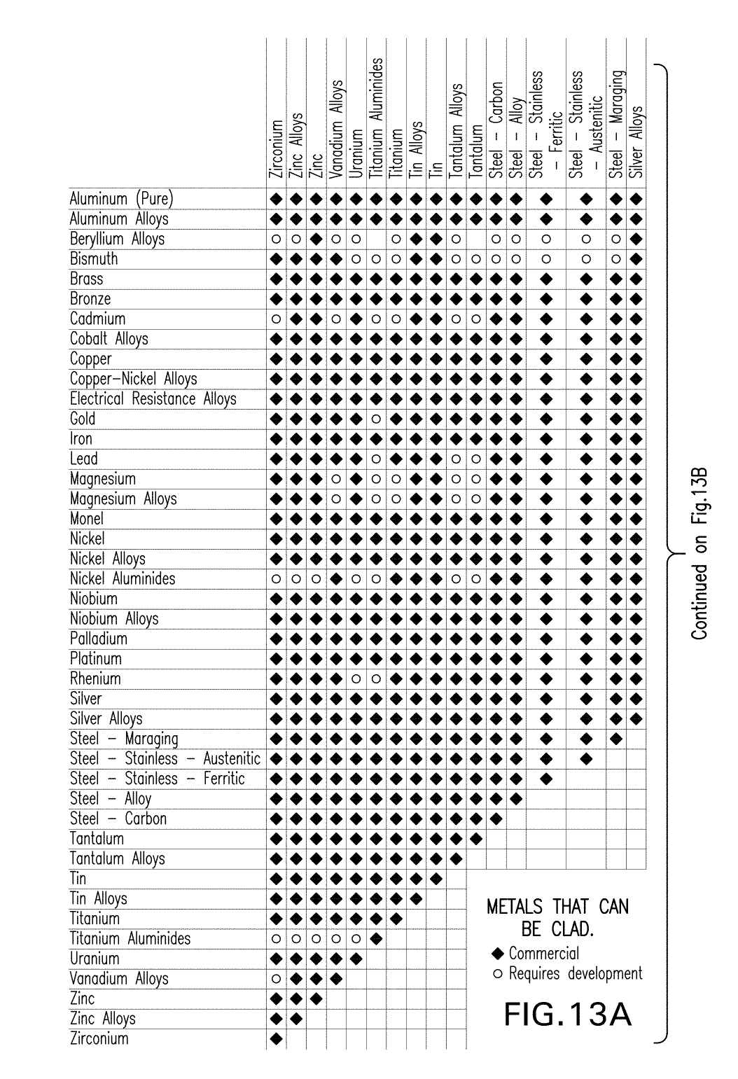

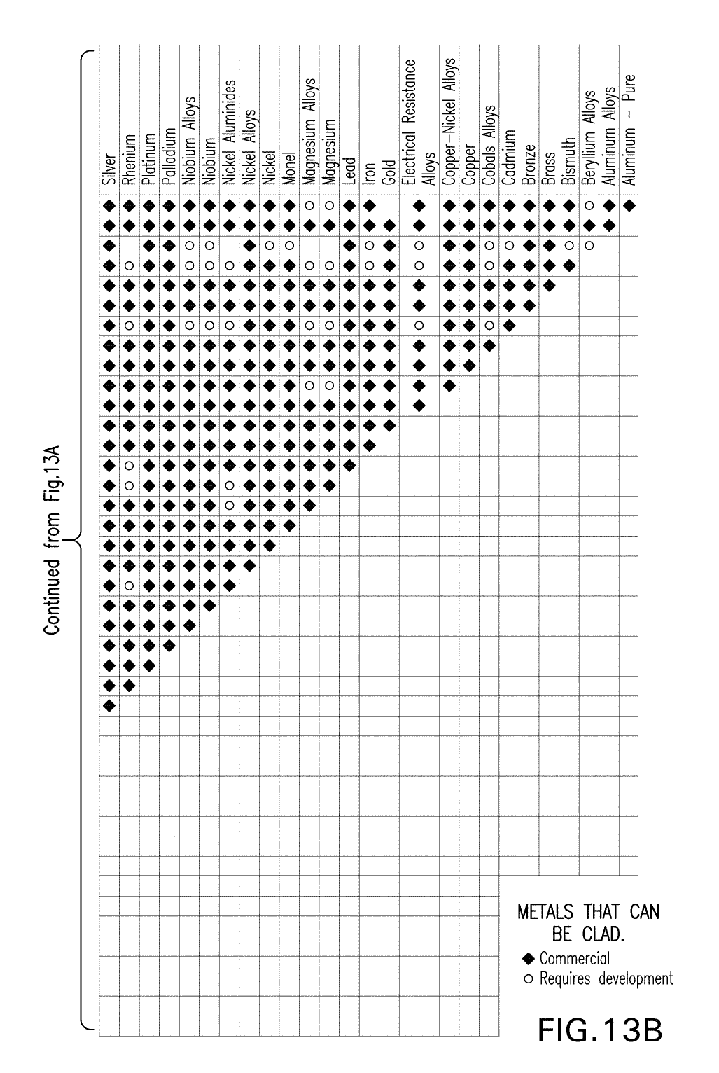

A multiple layer laminate composite or system 10 with thermal dispersion is described herein. In an aspect, the multiple layer laminate composite 10 can include thermal barriers that assist with the direction of thermal dispersion. Some layers of the multiple layer laminate composite 10 exhibit low electrical resistivity properties (i.e., high heat dispersion properties) while others exhibit high electrical resistivity properties (i.e., low heat dispersion properties). In an aspect, the different metals selected for the multiple layer laminate composite 10, and their properties, can include those in FIG. 13, with their properties listed in Table I, shown below. Additional properties, such as tensile strength, yield strength, and percent elongation, can also determine the components of the layers of the laminate composite 10.

TABLE I

| | | Thermal | | Thermal |
|---|---|---|---|---|
| | Temperature | Conductivity | Temperature | Conductivity |
| | - t - | - k - | - t - | - k - |
| Metal | (° F.) | (Btu/(hr ° F. ft)) | (° C.) | (W/m K) |
| Admiralty Brass | 68 | 64 | 20 | 111 |
| Aluminum, pure | 68 | 118 | 20 | 204 |
| | 200 | 124 | 93 | 215 |
| | 400 | 144 | 204 | 249 |
| Aluminum Bronze | 68 | 44 | 20 | 76 |
| Antimony | 68 | 10.7 | 20 | 19 |
| Beryllium | 68 | 126 | 20 | 218 |
| Beryllium Copper | 68 | 38 | 20 | 66 |
| Bismuth | 68 | 4.9 | 20 | 8.5 |
| Cadmium | 68 | 54 | 20 | 93 |
| Carbon Steel, max 0.5% C | 68 | 31 | 20 | 54 |
| Carbon Steel, max 1.5% C | 68 | 21 | 20 | 36 |
| | 752 | 19 | 400 | 33 |
| | 2192 | 17 | 1,200 | 29 |
| Cartridge brass | 68 | 69.4 | 20 | 120 |
| (UNS C26000) | | | | |
| Cast Iron, gray | 70 | 27-46 | 21 | 47-80 |
| Chromium | 68 | 52 | 20 | 90 |
| Cobalt | 68 | 40 | 20 | 69 |
| Copper, pure | 68 | 223 | 20 | 386 |
| | 572 | 213 | 300 | 369 |
| | 1112 | 204 | 600 | 353 |
| Copper bronze | 68 | 15 | 20 | 26 |
| (75% Cu, 25% Sn) | | | | |
| Copper brass | 68 | 64 | 20 | 111 |
| (70% Cu, 30% Zi) | | | | |
| Cupronickel | 68 | 17 | 20 | 29 |
| Gold | 68 | 182 | 20 | 315 |
| Hastelloy B | | 6 | | 10 |
| Hastelloy C | 70 | 5 | 21 | 8.7 |
| Inconel | 70-212 | 8.4 | 21-100 | 15 |
| Incoloy | 32-212 | 6.8 | 0-100 | 12 |
| Iridium | 68 | 85 | 20 | 147 |
| Iron, nodular pearlitic | 212 | 18 | 100 | 31 |
| Iron, pure | 68 | 42 | 20 | 73 |
| | 572 | 32 | 300 | 55 |
| | 1832 | 20 | 1,000 | 35 |
| Iron, wrought | 68 | 34 | 20 | 59 |
| Lead | 68 | 20 | 20 | 35 |
| | 572 | 17.2 | 300 | 30 |
| Manganese Bronze | 68 | 61 | 20 | 106 |
| Magnesium | 68 | 91.9 | 20 | 159 |
| Mercury | 68 | 4.85 | 20 | 8.4 |
| Molybdenum | 68 | 81 | 20 | 140 |
| Monel | 32-212 | 15 | 0-100 | 26 |
| Nickel | 68 | 52 | 20 | 90 |
| Nickel Wrought | 32-212 | 35-52 | 0-100 | 61-90 |
| Niobium (Columbium) | 68 | 30 | 20 | 52 |
| Osmium | 68 | 35 | 20 | 61 |
| Phosphor bronze | 68 | 28.9 | 20 | 50 |
| (10% Sn, UNS C52400) | | | | |
| Platinum | 68 | 42 | 20 | 73 |
| Plutonium | 68 | 4.6 | 20 | 8.0 |
| Potassium | 68 | 57.8 | 20 | 100 |
| Red Brass | 68 | 92 | 20 | 159 |
| Rhodium | 68 | 86.7 | 20 | 150 |
| Selenium | 68 | 0.3 | 20 | 0.52 |
| Silicon | 68 | 48.3 | 20 | 84 |
| Silver, pure | 68 | 235 | 20 | 407 |
| Sodium | 68 | 77.5 | 20 | 134 |
| Stainless Steel | 68 | 7-26 | 20 | 12-45 |
| Tantalum | 68 | 31 | 20 | 54 |
| Thorium | 68 | 24 | 20 | 42 |
| Tin | 32 | 36-39 | 0 | 62-68 |
| Titanium | 68 | 11-3 | 20 | 19-23 |
| Tungsten | 68 | 94-100 | 20 | 163-173 |
| Uranium | 68 | 14 | 20 | 24 |
| Vanadium | 68 | 35 | 20 | 61 |
| Wrought Carbon Steel | 32 | 34 | 0 | 59 |
| Yellow Brass | 68 | 67 | 20 | 116 |
| Zinc | — | 67 | | 116 |
| Zirconium | 32 | 13.4 | 0 | 23 |

In an aspect, the laminate composite 10 is manufactured by a “cold” bonding process known in the art, such as described in U.S. Pat. No. 8,420,225, herein incorporated and relied upon by reference. In other aspects, the laminate composite 10 can be formed through other methods known in the art.

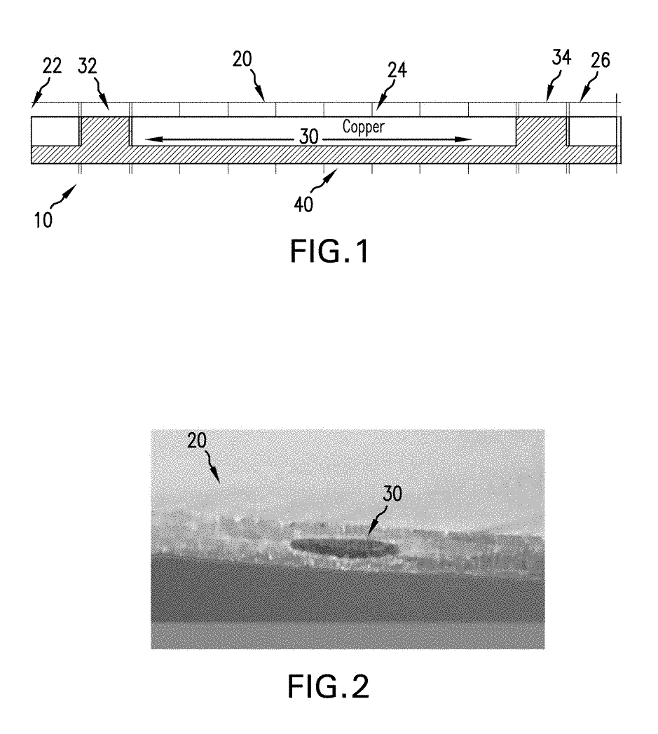

In an aspect, the metallic laminate composite 10 includes a first metallic layer 20 and thermal barriers 30 interlaid within the first metallic layer 20, as shown in FIGS. 1-9. The metallic laminate composite 10 can include additional metallic layers, discussed in more detail below. In an aspect, the first metallic layer 20 includes a metal having high heat dispersion characteristics. The first metallic layer 20 can include, but is not limited to, copper and copper alloys, aluminum and aluminum alloys, and the like. A thermal barrier 30 comprising a thermal blocking material is interlaid within the first metallic layer 20. In an aspect, the thermal barrier material 30 has low heat dispersion characteristics, which, when imbedded in the first metallic layer 20, creates isolated portions of the first metallic layer 20. By creating isolated portions of the first metallic layer 20, the thermal barrier 30 within the metallic composite 10 can control the areas in which heat dispersion occurs, as well as the direction of heat dispersion, in the first metallic layer 20.

In an aspect, the thermal barrier 30 of thermal blocking material has a low heat dispersion characteristic (i.e., high electrical resistivity characteristics). The high electrical resistivity will be dependent on the material utilized as well as the cross-sectional area of the thermal blocking material 30. In an aspect, the thermal barrier material 30 can include, but is not limited to, stainless steel, and the like. In addition, the thermal barrier material 30 can have additional properties, including, but not limited to magnetic properties. In an aspect, the thermal barrier material 30 are linear components 32, 34. In exemplary aspects, the linear components 32, 34 are three dimensional linear components 32, 34. For example, the thermal barrier material 30 can be stainless steel wires 32, 34. In an aspect, the cross-section shape of the three dimensional linear component(s) 32, 34 varies based upon the needs of the composite 10. The cross-sectional shape of the three dimensional linear component can include, but is not limited to, circular, oval, rectangular, square, triangular, and the like. In other aspects, the thermal barrier material 30 can be molded to take different forms and shapes. For example, if the composite 10 needs to have an isolated circular portion within the first metallic layer 20, the thermal barrier material 30 can be made to form a circle before bonding with the first metallic layer 20.

In an aspect, the thermal barrier material 30 is a harder/denser material than the first metallic layer 20, which allows the thermal barrier material 30 to be interlaid or embedded into the first metallic layer 20 during bonding. In a preferred aspect, the thermal barrier material 30 is interlaid within the first metallic layer 20 only through bonding. That is, the first metallic layer 20 does not have to be cut or grooved to receive the thermal barrier material 30. By eliminating cutting or grooving of the first metallic layer 20, the manufacturing process is simplified, eliminating steps. However, in other embodiments, cutting or grooving the material may need to be done. The properties of the materials and requirements of the final laminate composite 10, including geometrical and physical, can determine how the thermal barrier material 30 is interlaid within first metallic layer 20. FIG. 2 illustrates an example of a cross sectional view of an embodiment of the metallic laminate composite 10 with the thermal barrier material 30 interlaid within the first metallic layer 20. By being denser/harder, the thermal barrier material 30 is able to embed itself into the first metallic layer 20, and potentially isolate portions of the first metallic layer 20 from one another based upon the thermal barrier material 30 reducing thermal conductivity in the transition zone between the portions.

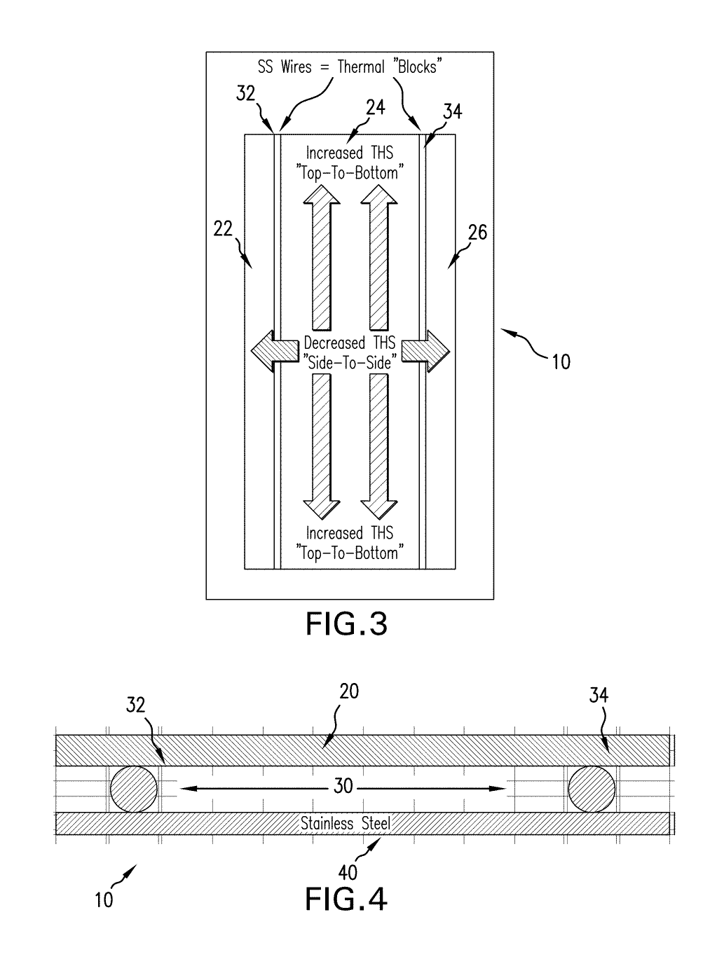

For example, FIG. 3 illustrates an example of a combination of the thermal barrier material components 32, 34 dividing the first metallic layer 20 into different components 22, 24, 26. As shown, the thermal barrier material components 32, 34 are linear components that extend the length of the first metallic layer 20. The linear components 32, 34 are spaced across the width of the first metallic layer 20 to create portions 22, 24, 26 that are thermally isolated from one another. The composite 10 of FIG. 3 ensures that thermal. heat spread (THS) that occurs in portion 24, the middle portion, does not spread side to side to the side isolated portions 22, 26. Such a composite would be useful in PEDs such as cell phones with their processors normally located towards the center of the PED, distributing the heat in a modified manner linear fashion along the length of the PED, and not along the width, protecting an individual's hand from exposure to higher temperatures (that is, a user's fingers hold the phone on the sides, i.e., the isolated side portions 22, 26). In other words, the thermal barrier components 32, 34 “block” thermal heat spread on the transverse or “side-to-side” direction, while also allowing for a higher percentage of high thermal dispersion material 20 within the inlays 32, 34 to increase the thermal heat spreading in the length or top-to-bottom direction of the cell phone as it is held in one's hand. In addition, as shown in examples below, the use of an overlay clad on the top and/or bottom of the core thermal center layer (i.e., the first metallic layer 20 having high heat dispersion proprieties) may be a benefit by controlling the heat spreading in the “Z” direction or through the PED cross-section.

As discussed above, the thermal barrier material 30 of the metallic laminate composite 10 is interlaid into the first metallic layer 20. The interla.y can occur through various means, including bonding, casting, and the like. However, there are advantages of interlaying the thermal barrier material 30 with the first metallic layer 20 through bonding, especially when the thermal barrier material 30 is harder than the first metallic layer 20 by eliminating the need to skive or form roll grooves from the first metallic layer 20 during manufacturing.

In an aspect, the metallic composite 10 can also include a second metallic layer 40. In such instances, the second metallic layer 40 differs from the first metallic layer 20 in properties. For example, as shown in FIGS. 1 and 4, the second metallic layer 40 can share properties with the thermal barrier material 30; i.e., the second metallic layer 40 can have low thermal dispersion characteristics. In some instances, the thermal barrier material 30 and the second metallic layer 40 are the same material. In an aspect, the second metallic layer 40 can be any clad metal option, including, but not limited to, stainless steel.

FIG. 4 illustrates the setup of the first metallic layer 20, the thermal barrier material 30, and a second metallic layer 40 according to an aspect of the present invention. As shown, two linear components 32, 34 of the thermal harrier material 30 are oriented between the first metallic layer 20 and the second metallic layer 40 before the bonding process occurs. In an aspect, the first metallic layer 20 is a softer material than the thermal barrier material 30 and the second metallic layer 40. In an exemplary aspect, the first metallic layer 20 comprises copper with the linear components 32, 34 and second metallic layer 40 comprising stainless steel. During bonding, the pressure applied on the first and second metallic layers 20, 40 on the thermal barrier material 30, and more specifically the components 32, 34, embeds the thermal barrier linear components 32, 34 within the first metallic layer 20, forming the separate sections 22, 24, 26. Once bonding occurs, the composite 10 is formed, as shown in FIG. 1. As shown in the cross-sectional view of FIG. 1, the linear components of the thermal barrier material 30 fully separate the portions 22, 24, 26 of the first metallic layer 20 from one another, limiting the THS within the first metallic layer 20 to the portion in which heat is applied.

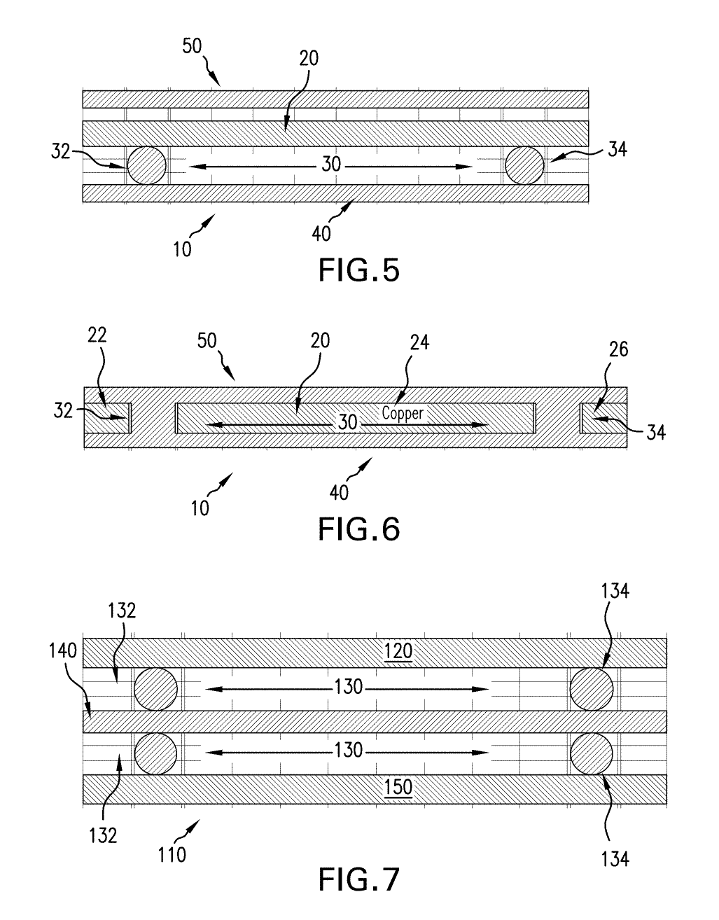

FIGS. 5-6 illustrate another embodiment of the metallic composite 10 according to another aspect of the present invention. As shown in FIGS. 5-6, the metallic composite 10 is made of three metallic layers 20, 40, 50 and the thermal barrier material 30. In an aspect, the thermal blocking material 30, and the second and third metallic layers 40, 50 are made from the same material having lower thermal dispersion properties and different density than the first metallic layer 20. In such instances, for example, the first metallic layer 20 can be a copper or copper alloy, and the remaining materials 30, 40, and 50 can be stainless steel. FIG. 5 illustrates the components 20, 30, 40, and 50 before bonding. As shown, the thermal barrier material 30 can be comprised of linear components 32, 34 (e.g., wire). Upon bonding, the second and third layers 40, 50 apply pressure on the linear components 32, 34, driving them through the first metallic layer 20 to create three distinct and isolated portions 22, 24, and 26, as shown in FIG. 6. In addition, the outer layers 40, 50, depending on their properties, can provide additional thermal barriers, increase the mechanical strength, corrosion resistance, and improve the cosmetic properties as well.

FIG. 7 illustrates a multi-layer metallic composite 110 according to another aspect. As shown, the metallic composite 110 includes first, second, and third layers 120, 140, 150 and thermal barrier material/components 130. The first and third layers 120, 150 have high heat dispersion properties. The second layer 140 and the thermal barrier materials 130 have lower dispersion properties and different densities. Upon bonding, the thermal barrier components 132, 134, with the assistance of the second layer 140, will divide the first and third layers into separate components.

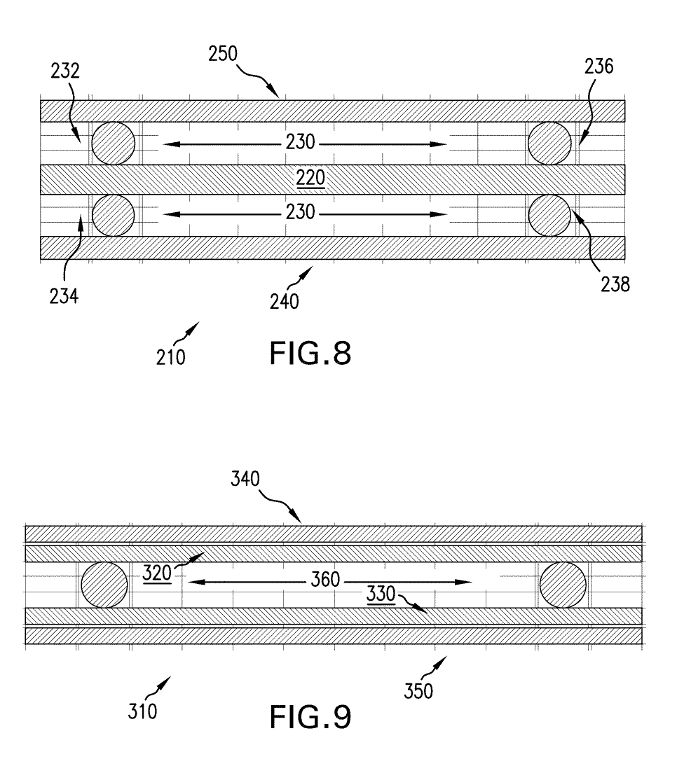

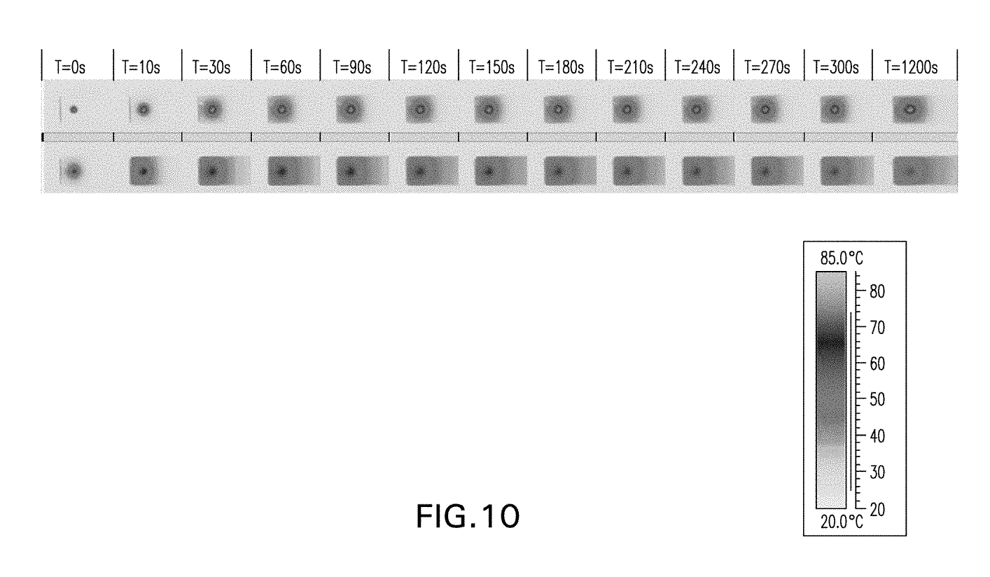

FIG. 8 illustrates a set up to make multi-layer metallic composite 210 having three layers 220, 240, and 250 and several thermal barrier components 232, 234, 236, 238 that, used in combination with the second and third metallic layers 240, 250 which shares similar properties (i.e. low heat dispersion and different density), divides up the first metallic layer 220 into several isolated portions (not shown).

FIG. 9 illustrates the set up to make a multi-layer metallic composite 310 made from four lavers 320, 330, 340, and 350. The first and second lavers 320, 330 are sandwiched between the third and fourth layers 340, 350. The first and second layers 320, 330 are oriented around the thermal barrier components 360. The first and second layers 320, 330 share thermal dispersion properties, while the third and fourth layers 340, 350, along with the thermal barrier components 360, share thermal dispersion and hardness properties. Upon bonding, the combination of the third and fourth layers 340, 350 with the thermal barrier components 360 bonds the first and second layers 320, 330 together while also creating isolated portions, similar to those described above.

In an aspect, the multi-layer metallic composite is configured to have a small thickness aimed at use in PEDs. For example, the composite can be approximately 0.15-0.25 millimeters thick. However, the composite can have greater or smaller thicknesses, depending upon the end requirements for the composite. For example, the composite can range between 0.01 to 1 millimeter. The thickness of the other components can vary to arrive at this thickness. in an aspect, it is more desirable to have the metallic layer with high heat dispersion properties make up the majority of the multi-layer metallic composite. For example, the metallic layer with high heat dispersion properties can make up approximately 50 to 75 percent of the overall thickness of the composite after bonding. However, in other embodiments, the high heat dispersion material can make up 90 percent of the overall thickness. The thickness may vary depending upon the ultimate needs of the multilayer metallic laminate composite 10.

Further, regardless of the final product desired, or the number of layers created, each material can be tempered and cleaned to remove organics and metal oxides in order to achieve maximum bond strength.

### EXAMPLE I

An illustrative and non-limiting method of making a metallic composite according to an aspect of the invention is detailed below:

Step 1—Make a BPlt (i.e., a “B” Plae or materials before subsequent bonding) of Copper with Nickel or Stainless Steel wire inlays—(using pre-grooved Copper to help track the wire into location). The composite was made with 0.031″ Copper and 0.032″ diameter Nickel wire. This was bonded to 0.019″, (˜40% Red), . . . the Nickel wire flatten to Thickness×Width=˜0.0115″×0.042″.

Step 2—Next Clean & Bond this 0.019″/0.020″ thick center layer of Copper with the inlay Nickel wires between two layers of Stainless Steel.

Step 3—Bond to 0.010″/0.012″ . . . (if bonding to 0.010″ is possible intermediate rolling and annealing can be avoided).

Step 4—and on—Sinter . . . Trim . . . Anneal . . . Roll . . . Clean . . . SBL Level . . . Slit

Testing of Heat Dispersion with CLAD Ratios of SS—Cu—SS

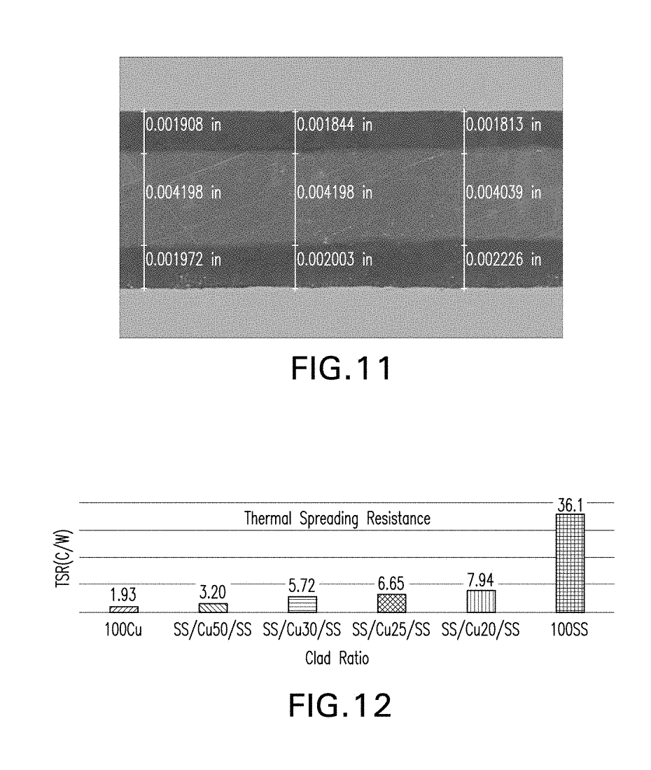

Table II below shows a relative comparison of thermal spreading resistance for various clad ratios of stainless steel—copper—stainless steel and includes 100 percent copper and 100 percent stainless steel as relative baselines, The theoretical thermal spreading resistance values shown below were calculated assuming the following: the indicated clad ratio is shown with the percentage of the middle layer having a certain percentage by volume of the clad material (e.g., SS/Cu50/SS means the copper middle layer comprises 50% of the voluvolume of the clad material); the overall material thickness combination is 0.20 mm; the thermal conductivity of the stainless steel (300 Series)equals 16.3 W/m−K; the thermal conductivity of the pure copper is 401 W/m−K; the heat source dimensions equaled 25 mm,(1.0″)×25 mm,(1.0″), with a heat load of 2 W; heat spreader dimensions: 76 mm,(3.0″)×127 mm,(5.0″); orientation of the material was horizontal (i.e., the typical orientation of a PED when held in a user's hand), and the heat transfer coefficient was 5 (based on Natural Convection—Flat Plate). In the SS/Cu50/SS configuration, a specific composite of 25/50/25 was used, with the composite density being 0.303 lbs/in\hat{ }3, (0.0084 kg/cm\hat{ }3) with an overall thickness of 0.0082″, (0.208 mm). The mechanical properties of the clad material are a result of a final roll % reduction, with the typical tempers annealed, ¼ hard and ½ hard. FIG. 11 illustrates a cross sectional view of the SS/Cu50/SS, with average thicknesses across the levels as the following: top SS—0.0019 in (0.048 mm), center Cu 0.0042 in (0.107 mm), bottom SS 0.0021 in (0.053 mm), and overall thickness 0.0082 in (0.208 mm).

TABLE II

| | 0.20 mm |
|---|---|
| 3-Layer | (0.0078″) |
| Clad Ratio | TSR (° C./W)* |
| 100Cu | 1.93 |
| SS/Cu50/SS | 3.20 |
| SS/Cu30/SS | 5.72 |
| SS/Cu25/SS | 6.65 |
| SS/Cu20/SS | 7.94 |
| 100SS | 36.1 |

FIG, 10 illustrates the heat dispersion comparison shown between pure 300 Stainless Steel (top row) and a clad material having a SS/Cu50/SS distribution (bottom row) over 1200 seconds. As shown, heat dispersion efficiency (value of thermal spreading resistance (TSR)) in pure 400 Series Stainless Steel is much less than that of pure Copper, 100% 300 Stainless Steel=36.1° C./W vs Copper=1.93° C./W. It can be estimated that pure Copper is ˜18.7 times better than pure 300 Series Stainless Steel when spreading heat. Therefore, combining different volumes of Copper and Stainless Steel as a Clad Laminate at different volume ratios will result in with various proportional heat dispersion efficiencies or TSRs as indicated in Table II above.

FIG. 12 illustrates the TSR in terms of C/W. As shown, pure copper has the lowest TSR (1.93) in comparison to SS 100 (36.1). All the clad materials had better TSRs than the SS, but SS/Cu50/SS had the next smallest TSR (3.20). In other words, the copper core layer has essentially 10× better Thermal Spreading Resistance than 100% Stainless Steel as illustrated for a Clad Ratio of 1-2-1 or 25% SS/50% Cu/25% SS, (ref SS/Cu50/SS in the graph), while still providing some mechanical, welding and cosmetic benefits of Stainless Steel as clad on the outer layers.

Having thus described exemplary embodiments of a method to produce metallic composite material, it should be noted by those skilled in the art that the within disclosures are exemplary only and that various other alternatives, adaptations, and modifications may be made within the scope of this disclosure, :Accordingly, the invention is not limited to the specific embodiments as illustrated herein, but is only limited by the following claims.

What is claimed is:

1. A metallic laminate composite comprising:
a. a first metallic layer having high heat dispersion characteristics; and
b. a thermal barrier material interlaid within the first metallic layer.

2. The metallic laminate composite of claim 1, wherein the thermal barrier material is interlaid into the first metallic layer through bonding.

3. The metallic laminate composite of claim 2, wherein the thermal barrier material is harder than the first metallic layer.

4. The metallic laminate composite of claim 3, wherein the thermal barrier material is interlaid within the first metallic layer to prevent heat dispersion throughout a portion of the first metallic layer.

5. The metallic laminate composite of claim 4, wherein the first metallic layer has a length and a width, and wherein the thermal barrier material comprises at least one linear component interlaid within and along the length of the first metallic layer.

6. The metallic laminate composite of claim 5, wherein the at least one linear component comprises two linear components finning the length of the first metallic layer in substantially the same direction to provide three distinct portions of the first metallic layer.

7. The metallic laminate composite of claim 5, wherein the at least one linear component comprises a wire.

8. The metallic laminate composite of claim 1, wherein the first metallic layer comprises copper or copper alloy.

9. The metallic laminate composite of claim 1, wherein the thermal barrier material comprises stainless steel.

10. The metallic laminate composite of claim 9, further comprising a second metallic layer bonded to the first metallic layer having high heat dispersion characteristics, the second metallic layer having lesser heat dispersion characteristics.

11. The metallic composite of claim 10, wherein the second metallic layer contacts the thermal barrier material.

12. The metallic laminate composite of claim 10, wherein the second metallic ayer comprises stainless steel.

13. The metallic laminate composite of claim 10, further comprising a third metallic layer, the third metallic layer having lesser heat dispersion characteristics and oriented adjacent the first metallic layer on the opposite side of the second metallic layer.

14. The metallic laminate composite of claim 10, further comprising a third metallic layer, the third metallic layer having high heat dispersion characteristics and located adjacent to the second metallic layer on a side opposite the first metallic layer, wherein the thermal barrier material is interlaid within the first and third metallic layers.
